(19) United States
(12) Patent Application Publication
(10) Pub. No.: US 2025/0391716 A1
(43) Pub. Date: Dec. 25, 2025

(54) RIVETED EDGE CORE FOR SEMICONDUCTOR PACKAGING

(71) Applicant: Intel Corporation, Santa Clara, CA (US)

(72) Inventors: Jeremy D. Ecton, Gilbert, AZ (US); Srinivas Venkata Ramanuja Pietambaram, Chandler, AZ (US); Brandon Christian Marin, Gilbert, AZ (US); Benjamin T. Duong, Phoenix, AZ (US); Gang Duan, Chandler, AZ (US)

(73) Assignee: Intel Corporation, Santa Clara, CA (US)

(21) Appl. No.: 18/750,423

(22) Filed: Jun. 21, 2024

(51) Int. Cl. H01L 23/15; C03B 23/203; C03C 15/00; H01L 23/498

(52) U.S. Cl. CPC H01L 23/15; C03B 23/203; C03C 15/00; H01L 23/49822; H01L 23/49827; H01L 23/49816

(57) ABSTRACT

Architectures and process flows for a riveted edge core component for semiconductor packaging. The core component includes a glass core defined by a planar area enclosed by one or more edges that are substantially orthogonal to the planar area and at least one through-glass via (TGV) in the layer of glass, substantially filled with a conductive material. The core component has a cavity extending laterally within at least one of the one or more edges. A dielectric material is in the cavity. The cavity is defined by a first sidewall extending at a first angle from an edge of the layer of glass towards a center point, and a second sidewall extending at a second angle from the edge of the layer of glass towards the center point. The first angle and the second angle are less than 45 degrees.

### BACKGROUND

Many semiconductor package architectures include a layer of glass or glass core to improve the dimensional stability of the substrate package; the improved dimensional stability enables placing more die on a single substrate package. However, the layer of glass can introduce technical challenges in the manufacturing process. Accordingly, improved architectures and methodologies for implementing a glass core are desired.

### BRIEF DESCRIPTION OF THE DRAWINGS

FIG. 1 is a simplified illustration of an example layer of glass with at least one riveted edge, in accordance with various embodiments.

FIG. 2 is a simplified cross-sectional view of a substrate package, in accordance with an embodiment.

FIG. 3 is a simplified cross-sectional view of a substrate package, in accordance with another embodiment.

FIGS. 4A, 4B, 4C, 4D, 4E, 5A, 5B, and 5C illustrate a simplified process flow for generating embodiments like FIG. 3, in accordance with various embodiments.

FIGS. 6A, 6B, and 6C illustrate a simplified process flow for generating embodiments like FIG. 2, in accordance with various embodiments.

FIG. 7 illustrates an example method for manufacturing and implementing a riveted edge core, in accordance with various embodiments.

FIG. 8 illustrates another example method for manufacturing and implementing a riveted edge core, in accordance with various embodiments.

FIGS. 9A, 9B, and 9C and FIGS. 10A, 10B, and 10C illustrate other supported variations on process flow and subsequent embodiments.

FIG. 11 is a top view of a wafer and dies that may be included in a microelectronic assembly, in accordance with any of the embodiments disclosed herein.

FIG. 12 is a simplified cross-sectional side view showing an implementation of an integrated circuit on a die that may be included in various embodiments, in accordance with any of the embodiments disclosed herein.

FIG. 13 is a cross-sectional side view of a microelectronic assembly that may include any of the embodiments disclosed herein.

FIG. 14 is a block diagram of an example electrical device that may include any of the embodiments disclosed herein.

### DETAILED DESCRIPTION

Many semiconductor package architectures utilize a layer of glass in an active area of a substrate component. The layer of glass offers many benefits, such as permitting smaller pitches and providing dimensional stability of the substrate component. Consequently, package architectures that implement a layer of glass can enable one larger, more complex die, and/or can enable placing more heterogeneous dies on a single substrate component, thereby resulting in more complex systems than a package architecture without a glass layer.

However, it is desirable to make the substrate components with a glass layer fungible with existing organic substrate components during the manufacturing process. One way to do that is to reconstitute them by individually encapsulating the glass core substrate components with mold or a dielectric material to reconstitute them into a desired planar area for manufacturing. Some technical challenges occur, such as delamination of the mold or dielectric material fabricated around the glass. The delamination can be induced by temperature or mechanical stresses and can reduce yield.

Embodiments described herein provide a technical solution to this technical challenge, and other advantages, in the form of architectures and process flows for riveted edge glass cores. Embodiments improve the adhesion between the layer of glass and the exterior matrix material, which is generally a mold or dielectric material. The practice of embodiments can be identified in individual substrate packages, microelectronic assemblies and final products, as well as in reconstituted wafers, sub-panels, and panels.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

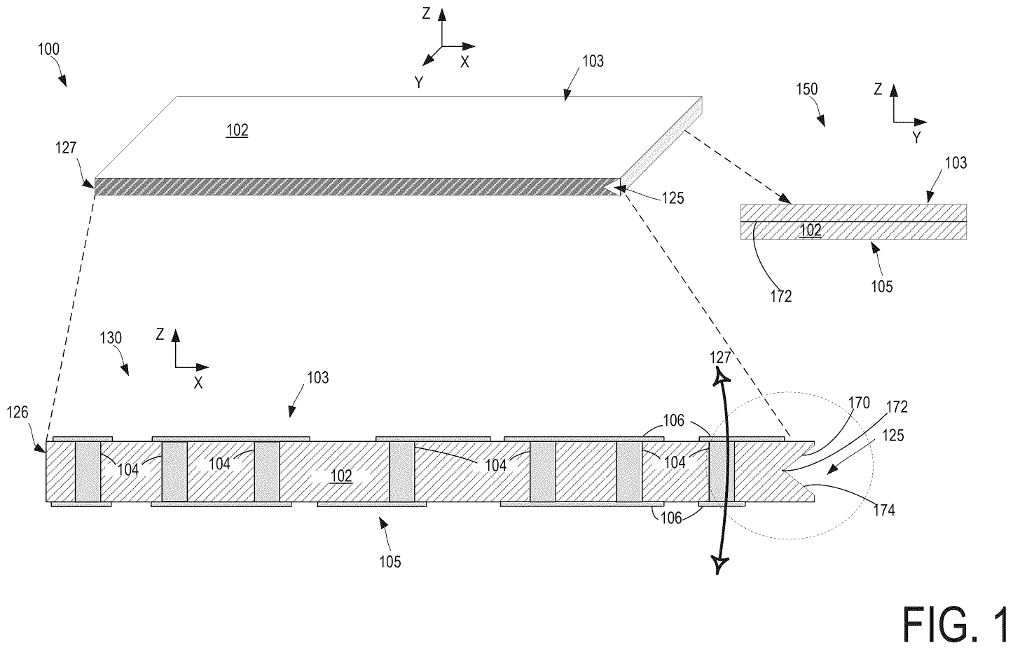

The non-limiting example in FIG. 1 is a simplified illustration of an example glass core or layer of glass with at least one riveted edge. The layer of glass 102 is a rectangular prism volume. Image 100 provides a framework for the layer of glass 102 in three dimensions, image 130 depicts the layer of glass 102 in an X-Z cross-sectional view, and image 150 depicts the layer of glass in a Y-Z cross-sectional view. The layer of glass 102 has at least one electrical path (illustrated with cartoon arrow 127) from the upper surface 103 of the layer of glass to the lower surface 105 of the layer of glass (through a through-glass via (TGV 104)) and is characterized by having at least one notched or riveted edge 125.

The layer of glass 102 comprises a layer of “glass.” As used herein, glass may comprise Silicon and Oxygen, as well as any one or more of Aluminum, Boron, Magnesium, Calcium, Barium, Tin, Sodium, Potassium, Strontium, Phosphorus, Zirconium, Lithium, Titanium, and Zinc. Non-limiting examples of glass include aluminosilicate, borosilicate, alumino-borosilicate, silica, and fused silica. In various embodiments, the glass may further include one or more additives, such as Al2O3, B2O3, MgO, CaO, SrO, BaO, SnO2, Na2O, K2O, SrO, P2O3, ZrO₂, Li2O, Ti, and Zn.

In some embodiments, the glass comprises at least 23 percent Silicon and at least 26 percent Oxygen by weight, and further comprises at least 5 percent Aluminum by weight. In some embodiments, the glass may be a photosensitive glass that belongs to the lithium-silicate family of glass (e.g., a glass comprising lithium, silicon, and oxygen) comprising metallic particles, such as gold, silver, or other suitable metallic particles. The layer of glass 102 may comprise multiple glass sheets fused or bonded together with an adhesion layer. The glass in the layer of glass 102 does not include an organic adhesive and the glass does not include an organic material. In various aspects of the disclosure, the layer of glass may be referred to as a solid layer of glass, even when constructed with a plurality of sheets of glass fused together, with the sections or TGVs removed.

In various embodiments, the layer of glass 102 may have a thickness (i.e., the Z direction in FIG. 1) that ranges from 20 microns+/−10% to 2 millimeters (mm)+/−10%. The layer of glass 102 may have a planar area (i.e., the Y-X directions in FIG. 1) that is defined by perimeter edges that are substantially orthogonal or perpendicular (i.e., 90 degrees plus or minus 18 degrees) to the planar area, the edges can have a length in a range of 10 millimeters (mm)+/−20% to 250 millimeters+/−20% (e.g., a panel can be 10 millimeters×10 millimeters up to 250 millimeters×250 millimeters). In the embodiment of the layer of glass 102, the glass comprises a rectangular prism volume with sections removed, those sections being the through-glass vias (TGV 104).

Variations of the embodiment of FIG. 1 advantageously can be reconstituted into a larger planar area (such as a wafer or panel) using a mold or dielectric material, the reconstituted planar area is then fungible with existing manufacturing flows for organic substrate components. The reconstituted planar area (i.e., the upper surface 103, as depicted in image 100) may be defined by a (X-Y) range of 10 millimeters+/−20% to 250 millimeters+/−20% (e.g., reconstituted into a panel that can be 10 millimeters×10 millimeters up to 250 millimeters×250 millimeters.

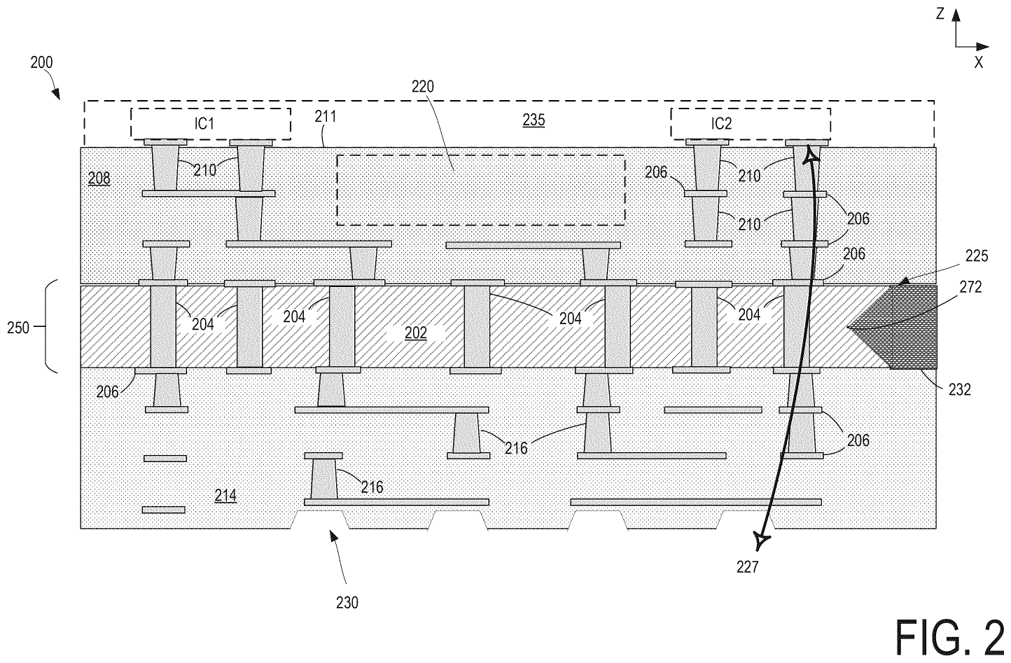

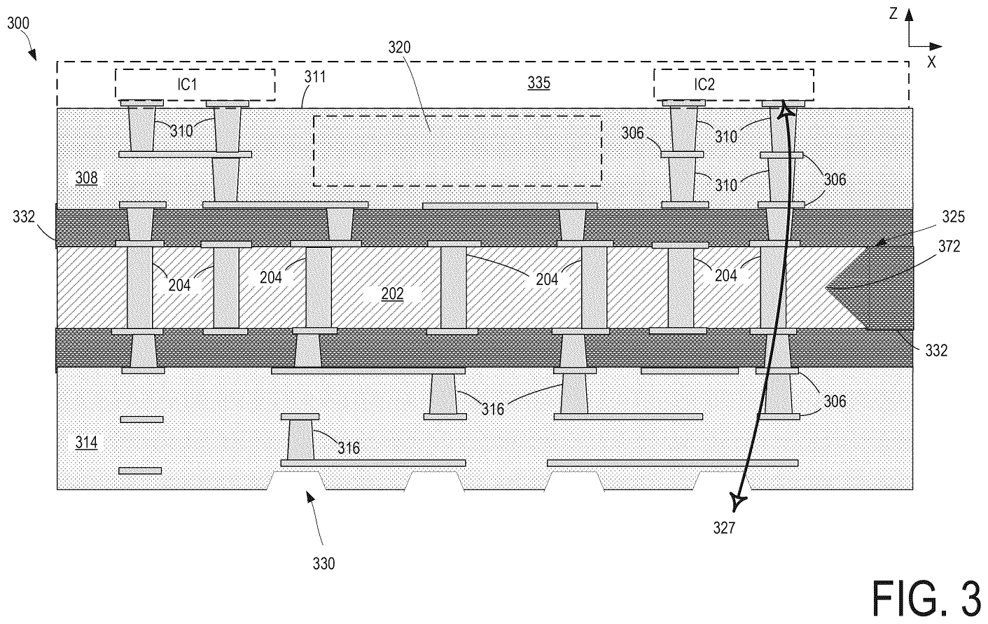

While aspects of this disclosure may be found in a variety of apparatuses, to identify embodiments of this disclosure, one can look, e.g., using SEM or TEM (transmission electron microscopy), at a portion of a substrate package architecture for a layer of glass that includes a riveted edge or cavity, and at least one electrical path from an upper surface 103 to a lower surface 105 (e.g., as indicated with the dashed oval).). The riveted edge 125 of the layer of glass, in practice, looks like a V-shaped cavity extending laterally (e.g., in the Y direction in image 150) within at least one of the one or more edges around the layer of glass 102. When reconstituted, the cavity has mold or dielectric material in it (see, e.g., mold 232, FIG. 2 and mold 332, FIG. 3). Having the mold in the at least one riveted edge improves the adhesion of the mold or dielectric material to the layer of glass 102 during manufacturing steps described below, when compared to the same component without the riveted edge or cavity.

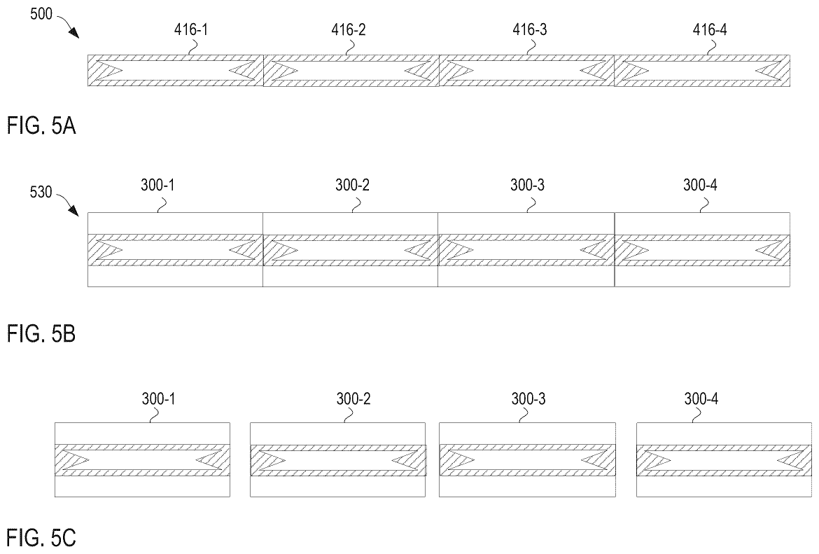

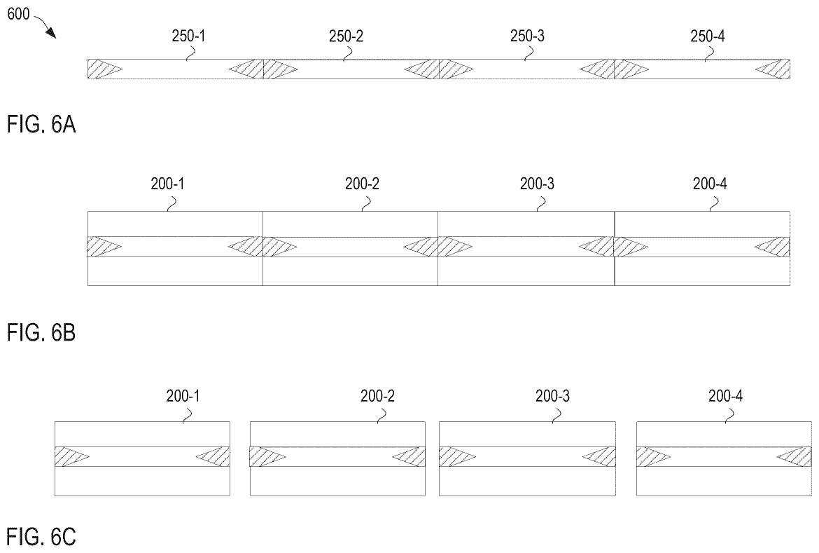

Note that image 130 is a two-dimensional cross-sectional drawing (e.g., Z-X in the drawing) showing a left and right side (on the page), the left side 126 not having a riveted edge, and the right side having a riveted edge 125; in another embodiment, the left side 126 may also have a riveted edge (see, e.g., FIGS. 5A-5C and 6A-6C), additionally, as the layer of glass is a rectangular prism volume with a planar area, there can also be a riveted edge in the +y direction and/or in the −y direction (in and out of the page, not shown in the figure). The riveted edge geometry, its creation, and its location in various embodiments are described below.

When viewed from the X-Z perspective, the cavity or riveted edge is characterized by a first sidewall 170 extending at a first angle (alpha 1, described below) from the upper surface 103 of the layer of glass 102 towards a center point 172, and a second sidewall 174 extending at a second angle (alpha 2, descried below) from a lower surface 105 of the layer of glass towards the center point 172. In various aspects of this disclosure, the first angle is less than 85 degrees, and the second angle is less than 85 degrees. In some embodiments, the first angle is further less than 45 degrees, and the second angle is further less than 45 degrees.

The first angle and the second angle may be equal, moreover, in some embodiments, such as those that utilize an alignment mechanism, the center point 172 may look like a point (e.g., as depicted in FIG. 2, 272 and FIG. 3, 372); or when viewed from the Y-Z perspective, the center point 172 may appear more like a line, as depicted in image 150.

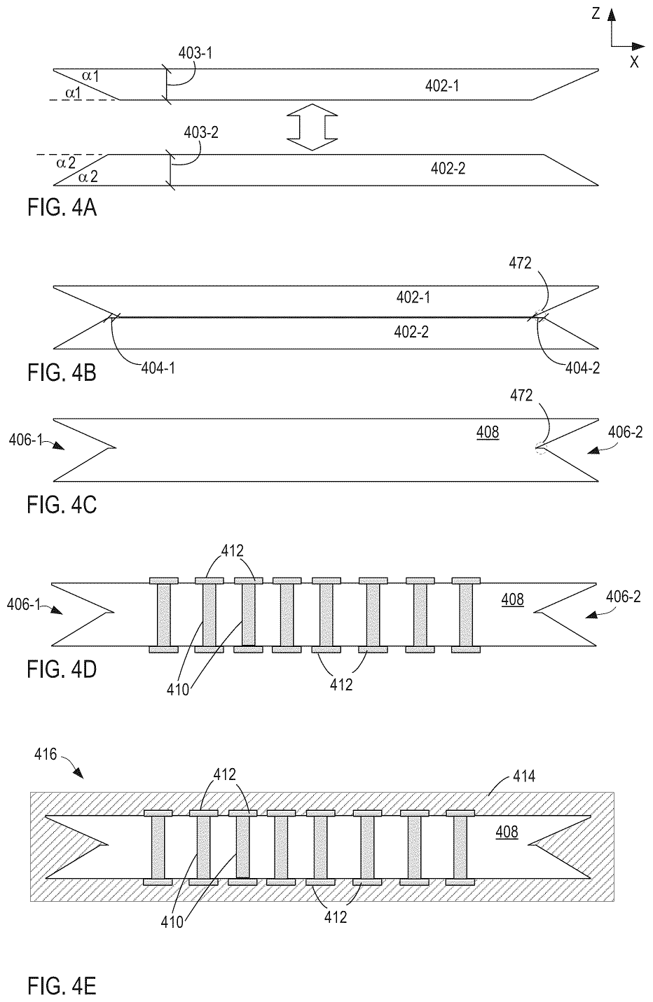

In other embodiments, the first angle and the second angle may be unequal; and further, the center point 172 may not be a perfect “point,” but can be an irregular ledge, due to an offset created during fabrication of the glass core, as described in connection with FIG. 4B (offset 404-2, leading to the center point appearing more like an irregular jag or notch 472). In a Y-Z perspective this variation may exhibit a center point that is jagged instead of straight.

FIGS. 2 and 3 illustrate some non-limiting features of systems and apparatuses that may exhibit aspects of this disclosure and FIGS. 4A to 10C provide additional information about intermediate embodiments, process steps, and fabrication.

As mentioned, the glass core, or layer of glass 102/202 with at least one riveted edge 125/225/325 is a substrate package component to fortify a substrate package. FIG. 2 is a simplified cross-sectional view of a first exemplary substrate package 200, and FIG. 3 is a simplified cross-sectional view of another exemplary substrate package 300. The substrate package view is sometimes referred to as a “substrate patch.” Dashed boxes in FIGS. 2 and 3 indicate optional variations, e.g., having integrated circuits attached, the ICs being overmolded or overlaid with an encapsulant, and/or having an embedded bridge component 220/320.

In the exemplary substrate package 200, the layer of glass 102/202 is sandwiched between dielectric layers (dielectric layer 208, dielectric layer 214) that include respective redistribution layers (RDL); the dielectric layers are substantially coplanar with the layer of glass, i.e., extending laterally left to right (along the X axis) above and below the layer of glass 202 or glass core in the figure; as illustrated. In the exemplary substrate package 300, the layer of glass 102/202 is again between coplanar dielectric layers (dielectric layer 308, dielectric layer 314) that include respective redistribution layers (RDL), however, the substrate package 300 has the mold or dielectric material 232/332 additionally on the upper surface and on the lower surface of the glass core, i.e., sandwiched between the layer of glass 202 and a respective dielectric layer (308/314).

The substrate package 200/300 has at least one electrical path 227/327 from the upper surface 211/311 of substrate package 200/300 to the lower surface.

Embodiments have a mold or dielectric material 232/332 around the perimeter (laterally) of the layer of glass 202 in the substrate package 200/300, as shown. The mold or dielectric material 232/332 at least partially fills the cavity created with the riveted edge 225/325. This dielectric material 232/332 is an indicator that at some point during manufacturing, the individual substrate package 200/300 was reconstituted into a larger planar area, such as a wafer, a panel, a quarter panel, or something similar.

The dielectric layers 208 and 214 can comprise a dielectric material, such as, a suitable nitride or oxide like silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), or hydrogen-doped silicon dioxide (H-doped SiO₂, which is a material that comprises silicon, oxygen, and hydrogen). In some embodiments, the dielectric material comprises a photo-imageable dielectric (PID). In some embodiments, the dielectric material comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

In some embodiments, it is advantageous for the dielectric layer 208 to have a CTE that matches that of target dies (e.g., match the CTE of silicon in an IC die such as IC1 and IC2 attached thereto). In some embodiments, the dielectric material can have a CTE that is close (e.g., within 10%) to that of silicon. In other embodiments, the dielectric material can be any type of epoxy molding compound. In some embodiments, the first dielectric layer 208 comprises the same dielectric material as the second dielectric layer 214; in other embodiments, the dielectric layer 208 comprises a different dielectric material from the second dielectric layer 214.

The electrical interconnections and electrical paths include pillars and redistribution layers (RDL), or conductive traces, layered and built into the dielectric layers. As used herein, redistribution layers (RDL) comprise metal or conductive traces or interconnects that connect or provide electrical paths between one region in a substrate package 200 to another region and are sufficient for electrical communication and/or for supplying power and ground. The RDL may be implemented in a “core geometry,” such as a 9/12 geometry (meaning a conductive trace width of 9 microns and a spacing of 12 microns). The RDL 206 may comprise a metal (e.g., copper, aluminum, nickel, cobalt, iron, tin, gold, silver, or combinations thereof) or another suitable conductive material. The RDL 206 may have a thickness (measured in the Z direction in the figure) from about 1 micron to 10 microns. In various embodiments, the RDL 206 may be substantially 5 microns. The RDL patterning may be performed using a modified semi-additive plating (MSAP) process, placing the RDL 206. Pillars/vias 210 and 216 provide vertical connectivity between layers of RDL 206, also comprise conductive material, and may be the same material as RDL 206.

Although dielectric layer 208 and dielectric layer 214 are each illustrated as one continuous dielectric layer, those with skill will appreciate that the dielectric layers 208/214 often each comprise 2 or more sub-dielectric layers, in a 1:1 relationship with the number of RDL 206 layers. For example, in FIG. 2, three RDL 206 layers are depicted in dielectric layer 208 and four RDL 206 layers are depicted in dielectric layer 214, this is a non-limiting example.

The layer of glass 202 is patterned with through-holes or through glass vias (TGVs) 204 that enable communication between the RDL in dielectric layer 208 and RDL in dielectric layer 214. As illustrated in the embodiment, the pillars/vias 210 and 216, as well as the TGVs 204 are substantially orthogonal or perpendicular (i.e., 90 degrees plus or minus 18 degrees) to the upper surface 211 of the substrate package 200.

The at least one electrical path from the upper surface of the layer of glass 202 to the lower surface of the layer of glass 202 e.g., through a through glass via (TGV 204) suitably filled with a conductive material, may be one segment in an electrical path from the upper surface 211 of the substrate package 200 to a lower surface of the substrate package 200; therefore, embodiments may also include, in the electrical path, one or more pillars 210/216 and RDL 206, as indicated with cartoon arrow 227.

In various embodiments, the substrate package 200 is part of a microelectronic assembly or system, as indicated with the dashed boxes for one or more ICs and the dashed box for potential encapsulant over the one or more ICs. As such, the substrate package 200 is to provide electrical interconnections between one or more integrated circuit (IC) dies and/or photonic integrated circuit (PIC) dies. Some, but not all, system configurations place the IC dies and/or PIC dies on the upper surface 211; further still, some configurations of the substrate package 200 implement one or more embedded bridge components (indicated generally by the dashed box 220/320) to provide some of the electrical interconnections between regions for IC dies on the substrate package 200. The substrate package 200 is further to provide electrical pathways between the upper surface 211 and a lower surface; the lower surface potentially for package pinouts, solder balls or bumps (e.g., in locations 230/330) and/or bonding on a package substrate, printed circuit board (PCB), or motherboard.

In various embodiments, such as when implemented in a packaged assembly, system, or a device, one or more die (e.g., IC1 and IC2) are attached to the substrate package 200/300 and then the die may be overmolded with an encapsulant 235/335. The encapsulant can comprise a molding compound, dielectric materials, metal, ceramic, plastic, or a combination thereof. Additionally, a thermal management solution (not shown) comprising a cooling component such as a vapor chamber, heat pipe, heat sink, or liquid-cooled cold plate may be attached to a substrate package 200. As part of a thermal management solution, a thermal conduction layer interface material (TIM) may be located over the die attached to the substrate package 200. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

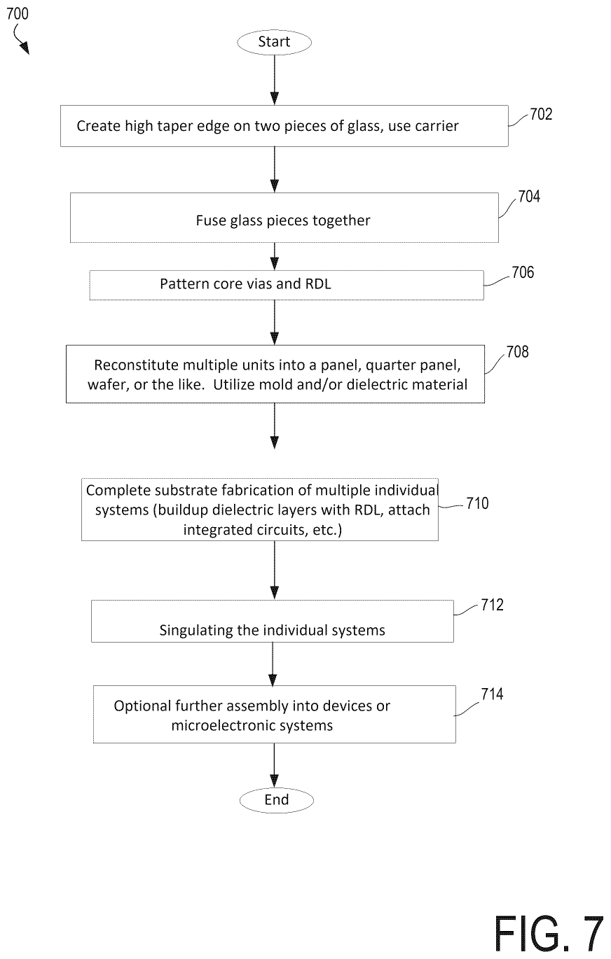

FIGS. 4A, 4B, 4C, 5A, 5B, and 5C illustrate a simplified process flow for generating systems based on variations of substrate package 300 FIG. 3. FIG. 7 provides a corresponding method 700 for making same. At 702, a first layer of glass 402-1 and a second layer of glass 402-2 are each chemically etched to create a high taper edge around their periphery. To achieve this, the first layer of glass 402-1 and the second layer of glass 402-2 may be removably attached to a carrier (not shown). As used herein the high taper edge is an angle (alpha 1 and alpha 2) of less than 45 degrees measured from the planar surfaces, as illustrated. The first layer of glass 402-1 has a thickness of 403-1 and the second layer of glass 402-2 has a thickness of 403-2. Note, that in some embodiments, alpha 1 is equal to alpha 2, and in other embodiments, alpha 1 is not equal to alpha 2.

In FIG. 4B, the first layer of glass 402-1 and the second layer of glass 402-2 have planar surfaces brought together to create the riveted edge, as shown. Although in many of the included figures, the riveted edge is depicted as a regular triangle, in practice, the riveted edge may have some irregularity due to variations in thickness of glass and/or due to variations in alpha 1 and alpha 2. In FIG. 4B, offset 404-1 is indicated at the left and offset 404-2 is indicated at the right. These offsets illustrate some of the ways the riveted edge can be irregular.

In FIG. 4C, (at 704) the two layers of glass are fused together into the glass core or layer of glass 408 (102, 202) that is described above. At 706, FIG. 4D, the layer of glass can be patterned with TGVs 410 and RDL 412. With reference back to FIG. 1, in some embodiments the center point 172 may be medial (or mid-way from top to bottom in the Z direction), indicating that the first layer of glass and the second layer of glass have substantially similar thicknesses. In other embodiments, the center point 172 may be closer to the top or closer to the bottom. In still other embodiments, described below, when a plurality of sheets of glass are fused together to create the glass core, there may be multiple rivets in the same edge, and in that case, there will be multiple center points, one for each rivet, and of course they will be stacked in the Z direction.

At 708, FIG. 4E, a mold or dielectric material 414 (232, 332) may be deposited over and around the architecture, at least partially filling the riveted edge, creating an intermediate embodiment 416. Multiple individual embodiments 416 can then be reconstituted into a larger planar area such as a panel, quarter panel, wafer, or the like, at 708. FIG. 5A provides a simplified image of an embodiment 500 of a reconstituted planar area that can be a panel, sub-panel, or wafer, in which intermediate embodiments 416-1, 416-2, 416-3, 416-4 are shown. Note that the images in FIG. 5A-5C leave out the details of the TGVs and RDL to make the image less busy.

As may be appreciated, although just 4 glass cores are depicted in the above description, in two dimensions, in practice, there may be a plurality of glass cores and subsequent systems, and they may be arranged in a round wafer, a square or rectangular panel, or other three-dimensional shape.

At 710, the reconstituted panel, wafer, etc. can be subjected to substrate fabrication as described above, wherein the intermediate embodiments 416-1, 416-2, 416-3, 416-4 are built up by adding layers of dielectric and RDL to create a respective multiple individual units or systems 300-1, 300-2, 300-3, and 300-4, as depicted in FIG. 5B. The detail of the buildup from fabrication is left out to simplify the images in 5B-5C; systems 300-1, 300-2, 300-3, and 300-4 reference FIG. 3, substrate package 300. In FIG. 5C, systems 300-1, 300-2, 300-3, and 300-4 can be singulated at 712. At 714, further assembly into devices or microelectronic systems may optionally be performed.

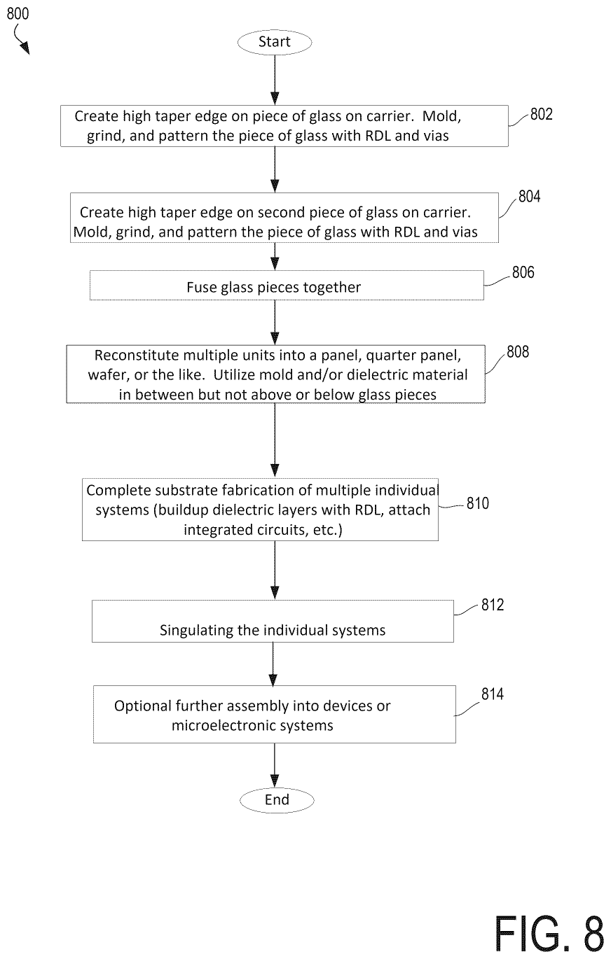

FIGS. 6A-6C illustrate a variation in the above-described processing methodology, to arrive at systems like the embodiment shown as substrate package 200 of FIG. 2, in which the glass core or layer of glass does not have the mold or dielectric on its upper surface or lower surface. FIG. 8 provides a method 800 for making the same. At 802 and 804, again, two separate glass cores are each chemically etched to create the high taper edge around their periphery (again, alpha 1 and alpha 2, as described above). In this process flow, the two separate glass cores are each attached to a carrier, and after having a high taper edge created, have mold applied over their upper surface (i.e., the non-carrier, or fusing surface, wherein the fusing surface has a smaller surface area than the carrier surface). The respective upper surfaces are ground down to reveal the fusing surfaces; in this manner, the mold is ensured to be around the periphery of the glass core prior to fusing the two glass cores together. Also at 802 and 804, after the mold and grind, the two glass cores may be separately patterned with TGVs and RDL. At 806, the two glass cores may be fused together at their fusing surfaces, and the earlier discussion about irregular riveted edge shape applies here as well.

FIG. 6A provides a simplified image of a reconstituted panel or wafer 600 at 808, in which intermediate embodiments 250-1, 250-2, 250-3, and 250-4 are shown. In these embodiments, the mold or dielectric material may occupy a larger percentage of the cavity created by the riveted edge, due to having been filled from above before the glass cores are fused together. Note that the images in FIG. 5A-5C leave out the details of the TGVs and RDL to make the image less busy, but intermediate embodiments 250-1, 250-2, 250-3, 250-4 correspond to the embodiment 250 in FIG. 2. As before, although just 4 glass cores are depicted in the above description, in two dimensions, in practice, there may be a plurality of glass cores and subsequent systems, and they may be arranged in a round wafer, a square or rectangular panel, or other three-dimensional shape.

At 810, the reconstituted panel or wafer 600 can be subjected to substrate fabrication as described above, wherein the intermediate embodiments 250-1, 250-2, 250-3, and 250-4 are built up with dielectric and RDL to create a respective multiple individual units or systems 200-1, 200-2, 200-3, and 200-4, as depicted in FIG. 6B. The detail of the buildup from fabrication is left out to simplify the images in 6B-6C; systems 200-1, 200-2, 200-3, and 200-4 reference FIG. 2 embodiment shown as substrate package 200. In FIG. 6C, systems 200-1, 200-2, 200-3, and 200-4 can be singulated at 812. At 814, further assembly into devices or microelectronic systems may optionally be performed.

In a processing variation to method 700 and/or method 800, at 702/802, a plurality of pieces of glass (e.g., sheets of glass) may respectively be etched to create the high taper edge as described hereinabove; and at 704/806, the plurality of sheets of glass, each with a high taper edge, can be fused together to create a solid piece of glass in which at least one perimeter edge has multiple rivets. In other words, in FIG. 1, where one riveted edge 125 is depicted, looking like a sideways V in the Z direction, there could instead be multiple rivets stacked on top of each other, creating a zig-zag profile in the Z direction, respective rivets extending from the perimeter edge inward. These fused sheets glass cores can be reconstituted (at 708/808) and fabricated into systems (at 710/810) as described above for the single riveted edge systems. In such a case, embodiments have a solid glass sheet comprising a plurality of sheets of glass fused together and embedded in the mold or dielectric material.

In a processing variation in which the glass core is created using a plurality of sheets of glass, the individual sheets of glass may be patterned with TGVs and RDL prior to fusing the sheets of glass, and the sheets of glass may then be hybrid bonded to other sheets of glass with TGVs.

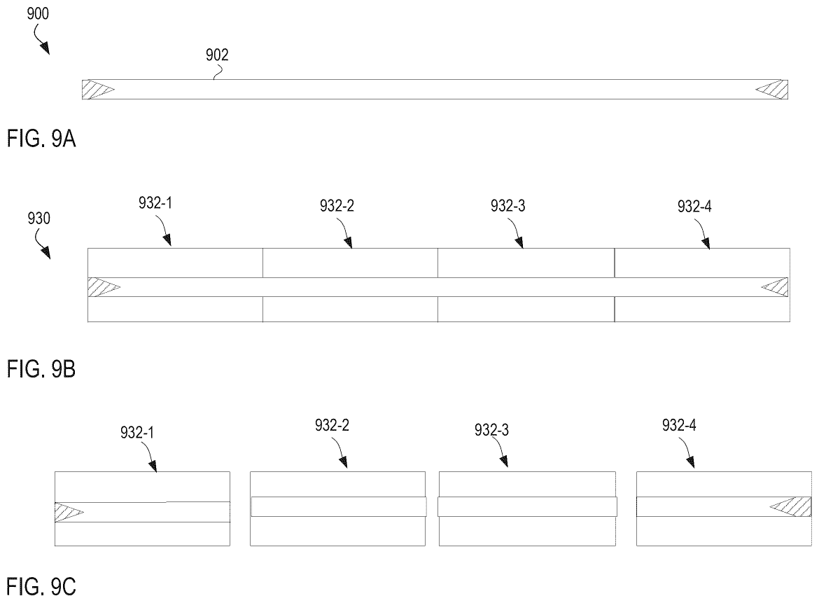

In FIG. 9A, a variation on FIG. 6A is illustrated, in which the riveted edge is only created around the perimeter, or outer periphery, of the panel 902 (note, panel 902 can also be a sub-panel, or wafer). In FIG. 9B, when the panel 902 gets built up into discrete systems in the fabrication process, systems 932-1. 932-2, 932-3, and 932-4 are created. Note that only system 932-1 and system 932-4 are depicted with the riveted edge, whereas system 932-2 and 932-3 have straight edges. Note also that only the riveted edges have the mold material 232/332 in the rivets, not the straight edges. In another embodiment, mold material can be utilized on the straight edges for the reconstitution of the panel. In other ways, the embodiments of 9A-9C are like the embodiments of 6A-6C.

In FIG. 9C, the multiple systems are singulated from the panel 902. Expand this two-dimensional drawing out into three-dimensions, and it is apparent that corner systems could have two of four riveted edges, with the mold material therein, and a plurality of inner systems may have no riveted edges.

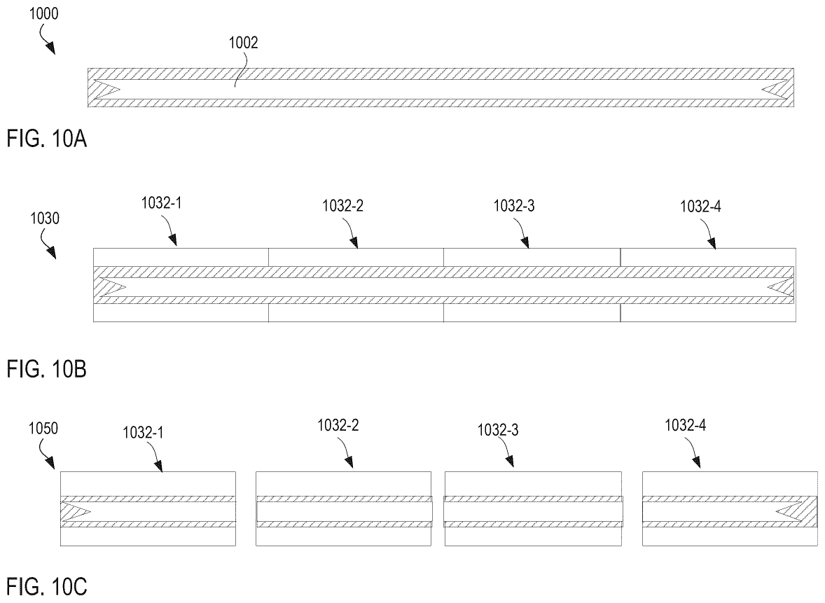

Similarly, FIG. 10A is a variation on FIG. 5A. Embodiment 1000 is similar to embodiment 500, except that the riveted edge is only created at the outer periphery of the panel 1002 (note, panel 1002 can also be a sub-panel, or wafer). In FIG. 10B, when the panel 902 gets built up into discrete systems in the fabrication process, systems 1032-1, 1032-2, 1032-3, and 1032-4 are created. Note that only system 1032-1 and system 1032-4 are depicted with the riveted edge in FIG. 10B. In FIG. 10C, the multiple systems are singulated from the panel 1002. Expand this two-dimensional drawing out into three-dimensions, and it is apparent that corner systems could have two of four riveted edges, and a plurality of inner systems may have no riveted edges.

Thus, various non-limiting embodiments of a riveted edge core for substrate components have been described. The following description provides additional details and context for various die and various package assembly and device configurations that can be created based on or using the provided embodiments.

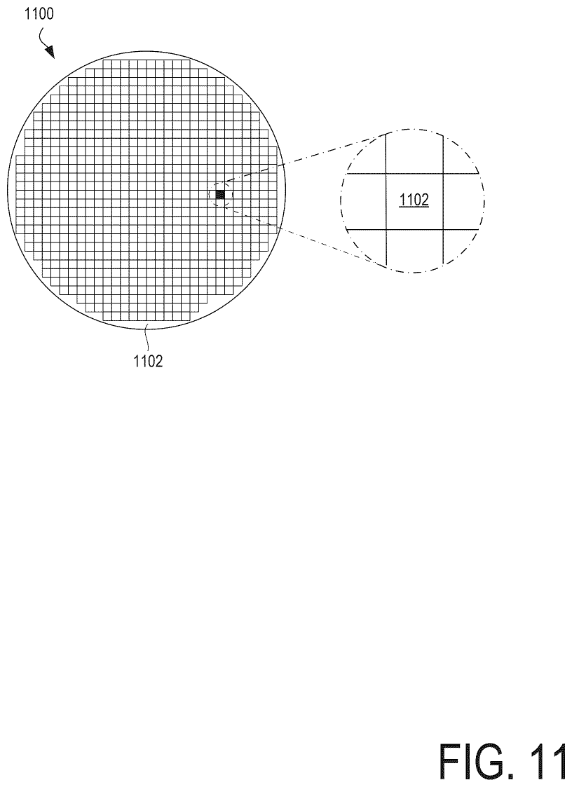

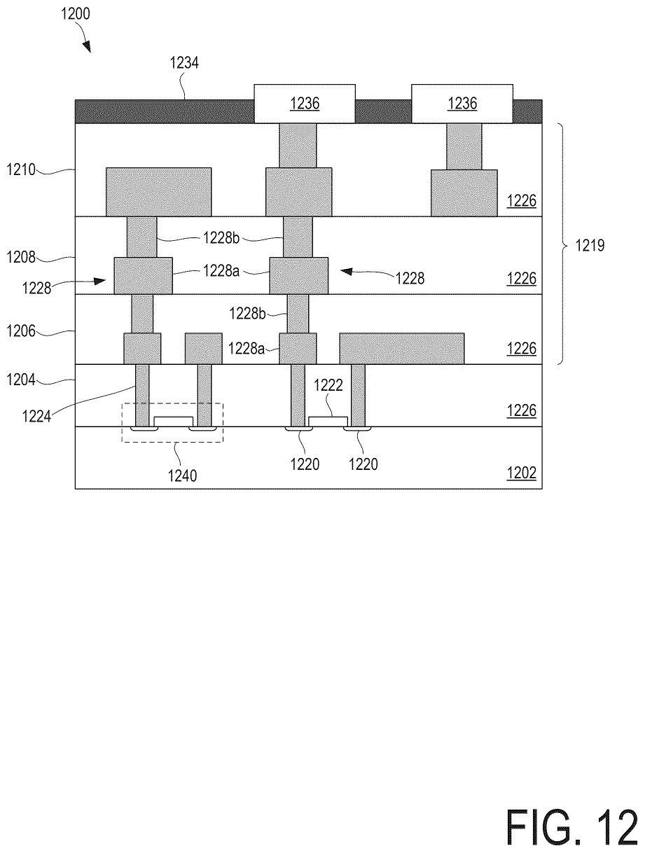

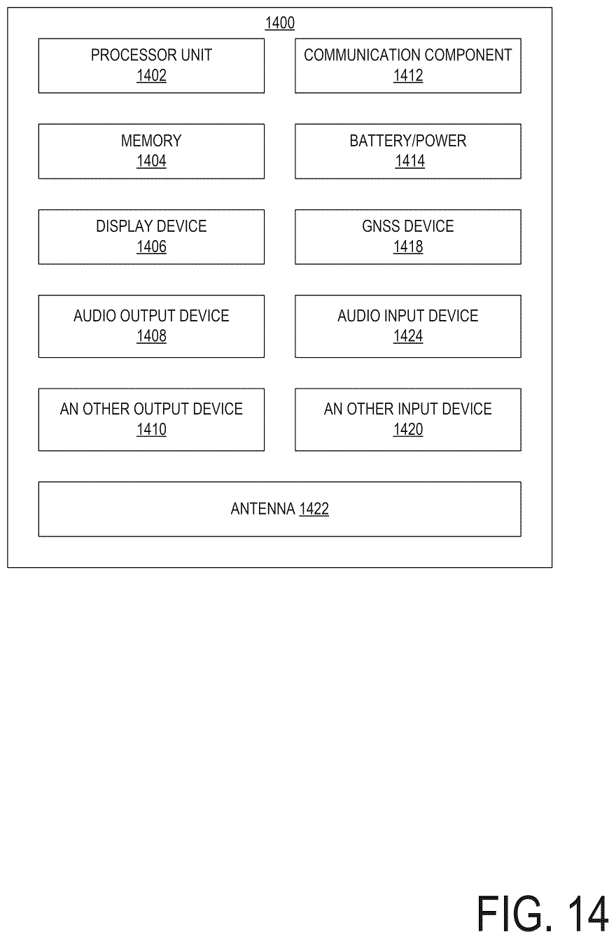

FIG. 11 is a top view of a wafer 1100 and dies 1102 that may be included in any of the embodiments disclosed herein. The wafer 1100 may be composed of semiconductor material and may include one or more dies 1102 formed on a surface of the wafer 1100. After the fabrication of the integrated circuit components on the wafer 1100 is complete, the wafer 1100 may undergo a singulation process in which the dies 1102 are separated from one another to provide discrete “chips” or destined for a packaged integrated circuit component. The individual dies 1102, comprising an integrated circuit component, may include one or more transistors (e.g., some of the transistors 1240 of FIG. 12, discussed below), supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 1102. For example, a memory array formed by multiple memory devices may be formed on a same die 1102 as a processor unit (e.g., the processor unit 1402 of FIG. 14) or other logic that is configured to store information in the memory devices or execute instructions stored in the memory array. In some embodiments, a die 1102 may be attached to a wafer 1100 that includes other die, and the wafer 1100 is subsequently singulated, this manufacturing procedure is referred to as a die-to-wafer assembly technique.

FIG. 12 is a cross-sectional side view of an integrated circuit 1200 that may be included in any of the embodiments disclosed herein. One or more of the integrated circuits 1200 may be included in one or more dies 1102 (FIG. 11). The integrated circuit 1200 may be formed on a die substrate 1202 (e.g., the wafer 1100 of FIG. 11) and may be included in a die (e.g., the die 1102 of FIG. 11).

The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit 1200 may be used. The die substrate 1202 may be part of a singulated die (e.g., the dies 1102 of FIG. 11) or a wafer (e.g., the wafer 1100 of FIG. 11).

The integrated circuit 1200 may include one or more device layers 1204 disposed on the die substrate 1202. The device layer 1204 may include features of one or more transistors 1240 (e.g., metal oxide semiconductor field-effect transistors (MOSFETs)) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220.

The gate 1222 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may comprise a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be conducted to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit 1200.

The interconnect structures 1228 may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuits having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page. The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the lines 1228 of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit 1200 (i.e., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices. For example, solder bonds may be formed on the one or more conductive contacts 1236 to mechanically and/or electrically couple an integrated circuit die including the integrated circuit 1200 with another component (e.g., a printed circuit board). The integrated circuit 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit 1200 is a double-sided die, the integrated circuit 1200 may include another metallization stack (not shown) on the opposite side of the device layer(s) 1204. This metallization stack may include multiple interconnect layers as discussed above with reference to the interconnect layers 1206-1210, to provide electrically conductive paths (e.g., including conductive lines and vias) between the device layer(s) 1204 and additional conductive contacts (not shown) on the opposite side of the integrated circuit 1200 from the conductive contacts 1236.

In other embodiments in which the integrated circuit 1200 is a double-sided die, the integrated circuit 1200 may include one or more through-silicon vias (TSVs) through the die substrate 1202; these TSVs may make contact with the device layer(s) 1204, and may provide electrically conductive paths between the device layer(s) 1204 and additional conductive contacts (not shown) on the opposite side of the integrated circuit 1200 from the conductive contacts 1236. In some embodiments, TSVs extending through the substrate can be used for routing power and ground signals from conductive contacts on the opposite side of the integrated circuit 1200 from the conductive contacts 1236 to the transistors 1240 and any other components integrated into the die 1200, and the metallization stack 1219 can be used to route I/O signals from the conductive contacts 1236 to transistors 1240 and any other components integrated into the die 1200.

Multiple integrated circuits 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

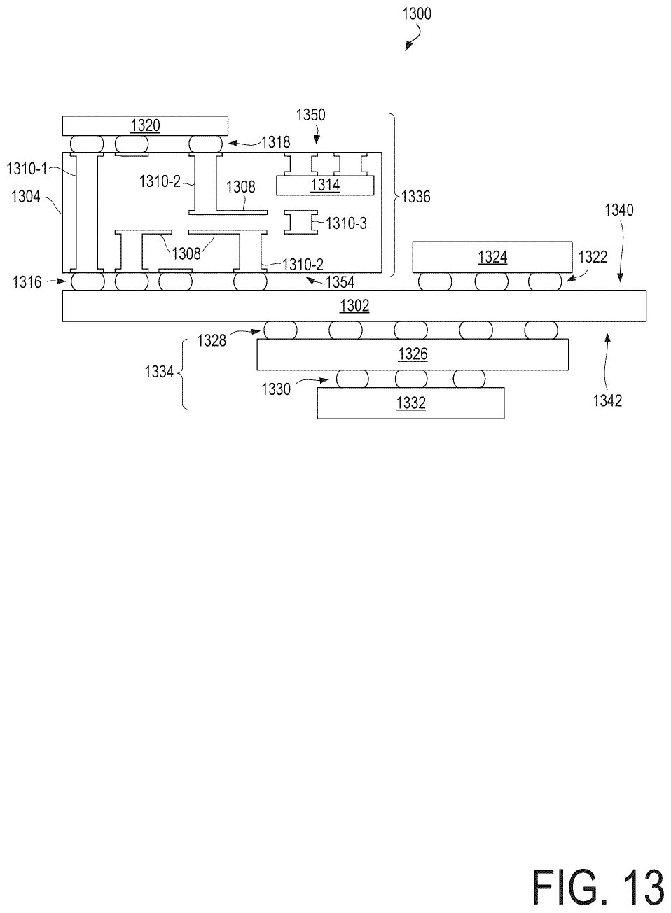

FIG. 13 is a cross-sectional side view of a microelectronic assembly 1300 that may include any of the embodiments disclosed herein. The microelectronic assembly 1300 includes multiple integrated circuit components disposed on a circuit board 1302 (which may be a motherboard, system board, mainboard, etc.). The microelectronic assembly 1300 may include components disposed on a first face 1340 of the circuit board 1302 and an opposing second face 1342 of the circuit board 1302; generally, components may be disposed on one or both faces 1340 and 1342.

In some embodiments, the circuit board 1302 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1302. In other embodiments, the circuit board 1302 may be a non-PCB substrate. The microelectronic assembly 1300 illustrated in FIG. 13 includes a package-on-interposer structure 1336 coupled to the first face 1340 of the circuit board 1302 by coupling components 1316. The coupling components 1316 may electrically and mechanically couple the package-on-interposer structure 1336 to the circuit board 1302, and may include solder balls (as shown in FIG. 13), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1336 may include an integrated circuit component 1320 coupled to an interposer 1304 by coupling components 1318. The coupling components 1318 may take any suitable form for the application, such as the forms discussed above with reference to the coupling components 1316. Although a single integrated circuit component 1320 is shown in FIG. 13, multiple integrated circuit components may be coupled to the interposer 1304; indeed, additional interposers may be coupled to the interposer 1304. The interposer 1304 may provide an intervening substrate used to bridge the circuit board 1302 and the integrated circuit component 1320.

The integrated circuit component 1320 may be a packaged or unpackaged integrated circuit component that includes one or more integrated circuit dies (e.g., the die 1102 of FIG. 11, the integrated circuit 1200 of FIG. 12) and/or one or more other suitable components.

The unpackaged integrated circuit component 1320 comprises solder bumps attached to contacts on the die. The solder bumps allow the die to be directly attached to the interposer 1304. In embodiments where the integrated circuit component 1320 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 1320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1304 may spread connections to a wider pitch or reroute a connection to a different connection. For example, the interposer 1304 may couple the integrated circuit component 1320 to a set of ball grid array (BGA) conductive contacts of the coupling components 1316 for coupling to the circuit board 1302. In the embodiment illustrated in FIG. 13, the integrated circuit component 1320 and the circuit board 1302 are attached to opposing sides of the interposer 1304; in other embodiments, the integrated circuit component 1320 and the circuit board 1302 may be attached to a same side of the interposer 1304. In some embodiments, three or more components may be interconnected by way of the interposer 1304.

In some embodiments, the interposer 1304 may be formed as a PCB, including multiple metal layers separated from one another by layers of dielectric material and interconnected by electrically conductive vias. In some embodiments, the interposer 1304 may be formed of an epoxy resin, a fiberglass-reinforced epoxy resin, an epoxy resin with inorganic fillers, a ceramic material, or a polymer material such as polyimide. In some embodiments, the interposer 1304 may be formed of alternate rigid or flexible materials that may include the same materials described above for use in a semiconductor substrate, such as silicon, germanium, and other group III-V and group IV materials. The interposer 1304 may include metal interconnects 1308 and vias 1310, including but not limited to through hole vias 1310-1 (that extend from a first face 1350 of the interposer 1304 to a second face 1354 of the interposer 1304), blind vias 1310-2 (that extend from the first or second faces 1350 or 1354 of the interposer 1304 to an internal metal layer), and buried vias 1310-3 (that connect internal metal layers).

In some embodiments, the interposer 1304 can comprise a silicon interposer. Through-silicon vias (TSV) extending through the silicon interposer can connect connections on the first face of a silicon interposer to an opposing second face of the silicon interposer. In some embodiments, an interposer 1304 comprising a silicon interposer can further comprise one or more routing layers to route connections on a first face of the interposer 1304 to an opposing second face of the interposer 1304.

The interposer 1304 may further include embedded devices 1314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1304. The package-on-interposer structure 1336 may take the form of any of the package-on-interposer structures known in the art.

The integrated circuit assembly 1300 may include an integrated circuit component 1324 coupled to the first face 1340 of the circuit board 1302 by coupling components 1322. The coupling components 1322 may take the form of any of the embodiments discussed above with reference to the coupling components 1316, and the integrated circuit component 1324 may take the form of any of the embodiments discussed above with reference to the integrated circuit component 1320.

The integrated circuit assembly 1300 illustrated in FIG. 13 includes a package-on-package structure 1334 coupled to the second face 1342 of the circuit board 1302 by coupling components 1328. The package-on-package structure 1334 may include an integrated circuit component 1326 and an integrated circuit component 1332 coupled together by coupling components 1330 such that the integrated circuit component 1326 is disposed between the circuit board 1302 and the integrated circuit component 1332. The coupling components 1328 and 1330 may take the form of any of the embodiments of the coupling components 1316 discussed above, and the integrated circuit components 1326 and 1332 may take the form of any of the embodiments of the integrated circuit component 1320 discussed above. The package-on-package structure 1334 may be configured in accordance with any of the package-on-package structures known in the art.

FIG. 14 is a block diagram of an example electrical device 1400 that may include one or more of the embodiments disclosed herein. For example, any suitable ones of the components of the electrical device 1400 may include one or more of the microelectronic assemblies 1300, integrated circuit components 1320, integrated circuits 1200, integrated circuit dies 1102, or structures disclosed herein. A number of components are illustrated in FIG. 14 as included in the electrical device 1400, but any one or more of these components may be omitted or duplicated, as suitable for the application. In some embodiments, some or all the components included in the electrical device 1400 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1400 may not include one or more of the components illustrated in FIG. 14, but the electrical device 1400 may include interface circuitry for coupling to the one or more components. For example, the electrical device 1400 may not include a display device 1406, but may include display device interface circuitry (e.g., a connector and driver circuitry) to which a display device 1406 may be coupled. In another set of examples, the electrical device 1400 may not include an audio input device 1424 or an audio output device 1408, but may include audio input or output device interface circuitry (e.g., connectors and supporting circuitry) to which an audio input device 1424 or audio output device 1408 may be coupled.

The electrical device 1400 may include one or more processor units 1402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1400 may include a memory 1404, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1404 may include memory that is located on the same integrated circuit die as the processor unit 1402. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1400 can comprise one or more processor units 1402 that are heterogeneous or asymmetric to another processor unit 1402 in the electrical device 1400. There can be a variety of differences between the processor units 1402 in a system in terms of a spectrum of metrics of merit including architectural, microarchitectural, thermal, power consumption characteristics, and the like. These differences can effectively manifest themselves as asymmetry and heterogeneity among the processor units 1402 in the electrical device 1400.

In some embodiments, the electrical device 1400 may include a communication component 1412 (e.g., one or more communication components). For example, the communication component 1412 can manage wireless communications for the transfer of data to and from the electrical device 1400. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1412 may operate in accordance with other wireless protocols in other embodiments. The electrical device 1400 may include an antenna 1422 to facilitate wireless communications and/or to receive other wireless communications (such as AM or FM radio transmissions).

In some embodiments, the communication component 1412 may manage wired communications, such as electrical, optical, or any other suitable communication protocols (e.g., IEEE 802.3 Ethernet standards). As noted above, the communication component 1412 may include multiple communication components. For instance, a first communication component 1412 may be dedicated to shorter-range wireless communications such as Wi-Fi or Bluetooth, and a second communication component 1412 may be dedicated to longer-range wireless communications such as global positioning system (GPS), EDGE, GPRS, CDMA, WiMAX, LTE, EV-DO, or others. In some embodiments, a first communication component 1412 may be dedicated to wireless communications, and a second communication component 1412 may be dedicated to wired communications.

The electrical device 1400 may include battery/power circuitry 1414. The battery/power circuitry 1414 may include one or more energy storage devices (e.g., batteries or capacitors) and/or circuitry for coupling components of the electrical device 1400 to an energy source separate from the electrical device 1400 (e.g., AC line power).

The electrical device 1400 may include a display device 1406 (or corresponding interface circuitry, as discussed above). The display device 1406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1400 may include an audio output device 1408 (or corresponding interface circuitry, as discussed above). The audio output device 1408 may include any embedded or wired or wirelessly connected external device that generates an audible indicator, such speakers, headsets, or earbuds.

The electrical device 1400 may include an audio input device 1424 (or corresponding interface circuitry, as discussed above). The audio input device 1424 may include any embedded or wired or wirelessly connected device that generates a signal representative of a sound, such as microphones, microphone arrays, or digital instruments (e.g., instruments having a musical instrument digital interface (MIDI) output). The electrical device 1400 may include a Global Navigation Satellite System (GNSS) device 1418 (or corresponding interface circuitry, as discussed above), such as a Global Positioning System (GPS) device. The GNSS device 1418 may be in communication with a satellite-based system and may determine a geolocation of the electrical device 1400 based on information received from one or more GNSS satellites, as known in the art.

The electrical device 1400 may include another output device 1410 (or corresponding interface circuitry, as discussed above). Examples of the other output device 1410 may include an audio codec, a video codec, a printer, a wired or wireless transmitter for providing information to other devices, or an additional storage device.

The electrical device 1400 may include another input device 1420 (or corresponding interface circuitry, as discussed above). Examples of the other input device 1420 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1400 may be any other electronic device that processes data. In some embodiments, the electrical device 1400 may comprise multiple discrete physical components. Given the range of devices that the electrical device 1400 can be manifested as in various embodiments, in some embodiments, the electrical device 1400 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, or the like, means that all the items in the list possess the stated or recited trait, feature, or the like. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Unless otherwise stated, terms or values modified by the word “substantially” include arrangements, orientations, spacings, or positions that vary plus or minus 20% from the meaning of the unmodified term or value. Terms or values modified by the word “about” include values inclusive of 10% less than the term or value to inclusive of 10% greater than the term or value.

As used herein, the term “electronic component” can refer to an active electronic circuit (e.g., processing unit, memory, storage device, FET) or a passive electronic circuit (e.g., resistor, inductor, capacitor).

As used herein, the term “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die (shortened herein to “die”); the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

The following examples pertain to additional embodiments of technologies disclosed herein.

### EXAMPLES

Example 1 is a substrate package component, comprising: a layer of glass comprising a rectangular prism volume defined by a planar area enclosed by one or more edges that are substantially orthogonal to the planar area; a through-glass via (TGV) in the layer of glass, the TGV substantially filled with a conductive material; a cavity extending laterally within at least one of the one or more edges; and a dielectric material in the cavity.

Example 2 includes the subject matter of Example 1, wherein: the layer of glass comprises a thickness; the cavity is defined by a first sidewall extending at a first angle from an upper surface of the layer of glass towards a center point, and a second sidewall extending at a second angle from a lower surface of the layer of glass towards the center point; and wherein the first angle is less than 85 degrees, and the second angle is less than 85 degrees.

Example 3 includes the subject matter of Example 2, wherein the first angle is less than 45 degrees, and the second angle is less than 45 degrees.

Example 4 includes the subject matter of Example 1, wherein the layer of glass has a thickness in a range of 20 microns+/−20% to 2 millimeters+/−20%.

Example 5 includes the subject matter of Example 1, wherein: a first edge of the one or more edges has a length in a range of 10 millimeters (mm)+/−20% to 250 mm+/−20%; and a second edge of the one or more edges is perpendicular to the first edge and has a length in a range of 10 mm+/−20% to 250 mm+/−20%.

Example 6 includes the subject matter of Example 1, further comprising a first layer of the dielectric material on an upper surface of the layer of glass and a second layer of the dielectric material on a lower surface of the layer of glass, and wherein the first layer of the dielectric material, the second layer of the dielectric material, and the dielectric material in the cavity are contiguous.

Example 7 includes the subject matter of Example 1, wherein the TGV is one of a plurality of TGVs that are patterned in the layer of glass and substantially filled with the conductive material.

Example 8 is a substrate package, comprising: a first dielectric layer comprising a plurality of first redistribution layers (RDL) therein; a solid layer of glass under the first dielectric layer, the solid layer of glass defined by a planar area enclosed by one or more perimeter edges that are substantially orthogonal to the planar area; wherein the solid layer of glass comprises at least 23 percent Silicon and at least 26 percent Oxygen by weight, and at least 5 percent Aluminum by weight; a through-glass via (TGV) substantially filled with a conductive material; one or more cavities extending laterally within at least one of the one or more perimeter edges; and a mold material in the one or more cavities; a second dielectric layer below the solid layer of glass, the second dielectric layer comprising a plurality of second RDL therein; and at least one electrical path from an upper surface of the first dielectric layer through the TGV to a lower surface of the second dielectric layer.

Example 9 includes the subject matter of Example 8, wherein: the solid layer of glass comprises a thickness measured in a first direction; and individual cavities of the one or more cavities are stacked in the first direction; wherein individual cavities are defined by a first sidewall extending at a first angle of less than 85 degrees from a perimeter edge of the solid layer of glass towards a center point, and a second sidewall extending at a second angle of less than 85 degrees from the perimeter edge of the solid layer of glass towards the center point.

Example 10 includes the subject matter of Example 9, wherein the first angle is less than 45 degrees, and the second angle is less than 45 degrees.

Example 11 includes the subject matter of Example 8, wherein the solid layer of glass has a thickness in a range of 20 microns+/−20% to 2 millimeters+/−20%.

Example 12 includes the subject matter of Example 8, wherein: a first edge of the one or more edges has a length in a range of 10 millimeters (mm)+/−20% to 250 mm+/−20%; and a second edge of the one or more edges is perpendicular to the first edge and has a length in a range of 10 mm+/−20% to 250 mm+/−20%.

Example 13 includes the subject matter of Example 8, further comprising: an integrated circuit (IC) die attached on the upper surface of the first dielectric layer; and an encapsulant overlaid across the IC die.

Example 14 includes the subject matter of Example 8, further comprising solder bumps attached to the lower surface of the second layer.

Example 15 includes the subject matter of Example 8, further comprising: a first layer of the mold material between the first dielectric layer and the solid layer of glass; a second layer of the mold material between the solid layer of glass and the second dielectric layer; and wherein the first layer of the mold material, the second layer of the mold material, and the mold material in the cavity are contiguous.

Example 16 includes the subject matter of Example 15, further comprising: an integrated circuit (IC) die attached on the upper surface of the first dielectric layer; and solder bumps attached to the lower surface of the second layer.

Example 17 is a device, comprising: the subject matter of Example 14; and a printed circuit board attached to the solder bumps.

Example 18 includes the subject matter of Example 15, further comprising solder bumps attached to the lower surface of the second layer.

Example 19 includes the subject matter of Example 18, further comprising: an integrated circuit (IC) die attached on the upper surface of the first dielectric layer; and solder bumps attached to the lower surface of the second layer.

Example 20 is a device, comprising: the subject matter of Example 19; and a printed circuit board attached to the solder bumps.

Example 21 is a method, comprising: etching a first top side of a first layer of glass to create a first high taper edge from the first top side to a first bottom side; etching a second top side of a second layer of glass to create a second high taper edge from the second top side to a second bottom side; fusing the first top side to the second top side to thereby create a glass core with a riveted edge; patterning the glass core with the riveted edge with through-glass vias (TGVs) and redistribution layers to thereby create a unit; reconstituting the unit with a plurality of similar units thereby creating a panel, wherein reconstituting includes using a mold material and at least partially filling the riveted edge.

Example 22 includes the subject matter of Example 21, further comprising: completing substrate fabrication on the units in the panel by adding dielectric layers and additional redistribution layers.

Example 23 includes the subject matter of Example 22, further comprising singulating the panel into discrete systems.

Example 24 includes the subject matter of Example 23, further comprising attaching an integrated circuit die to a first surface of a discrete system and attaching solder bumps to a second surface of the discrete system.

Example 25 includes the subject matter of Example 24, further comprising attaching a printed circuit board to the solder bumps.

Example 26 includes the subject matter of Example 25, further comprising attaching a power supply to the printed circuit board and communicatively coupling the integrated circuit die to the power supply.

What is claimed is:

1. A substrate package component, comprising:
a layer of glass comprising a rectangular prism volume defined by a planar area enclosed by one or more edges that are substantially orthogonal to the planar area;
a through-glass via (TGV) in the layer of glass, the TGV substantially filled with a conductive material;
a cavity extending laterally within at least one of the one or more edges; and
a dielectric material in the cavity.

2. The substrate package component of claim 1, wherein:
the layer of glass comprises a thickness;
the cavity is defined by a first sidewall extending at a first angle from an upper surface of the layer of glass towards a center point, and a second sidewall extending at a second angle from a lower surface of the layer of glass towards the center point; and
wherein the first angle is less than 85 degrees, and the second angle is less than 85 degrees.

3. The substrate package component of claim 2, wherein the first angle is less than 45 degrees, and the second angle is less than 45 degrees.

4. The substrate package component of claim 1, wherein the layer of glass has a thickness in a range of 20 microns+/−20% to 2 millimeters+/−20%.

5. The substrate package component of claim 1, wherein:
a first edge of the one or more edges has a length in a range of 10 millimeters (mm)+/−20% to 250 mm+/−20%; and
a second edge of the one or more edges is perpendicular to the first edge and has the length in a range of 10 mm+/−20% to 250 mm+/−20%.

6. The substrate package component of claim 1, further comprising a first layer of the dielectric material on an upper surface of the layer of glass and a second layer of the dielectric material on a lower surface of the layer of glass, and wherein the first layer of the dielectric material, the second layer of the dielectric material, and the dielectric material in the cavity are contiguous.

7. The substrate package component of claim 1, wherein the TGV is one of a plurality of TGVs that are patterned in the layer of glass and substantially filled with the conductive material.

8. A substrate package, comprising:
a first dielectric layer comprising a plurality of first redistribution layers (RDL) therein;
a layer of glass under the first dielectric layer, the layer of glass defined by a planar area enclosed by one or more perimeter edges that are substantially orthogonal to the planar area;
wherein the layer of glass comprises at least 23 percent Silicon and at least 26 percent Oxygen by weight, and at least 5 percent Aluminum by weight; a through-glass via (TGV) substantially filled with a conductive material; one or more cavities extending laterally within at least one of the one or more perimeter edges; and a mold material in the one or more cavities;
a second dielectric layer below the layer of glass, the second dielectric layer comprising a plurality of second RDL therein; and
at least one electrical path from an upper surface of the first dielectric layer through the TGV to a lower surface of the second dielectric layer.

9. The substrate package of claim 8, wherein:
the layer of glass comprises a thickness measured in a first direction; and
individual cavities of the one or more cavities are stacked in the first direction;
wherein individual cavities are defined by a first sidewall extending at a first angle of less than 85 degrees from a perimeter edge of the layer of glass towards a center point, and a second sidewall extending at a second angle of less than 85 degrees from the perimeter edge of the layer of glass towards the center point.

10. The substrate package of claim 9, wherein the first angle is less than 45 degrees, and the second angle is less than 45 degrees.

11. The substrate package of claim 8, wherein the layer of glass has a thickness in a range of 20 microns+/−20% to 2 millimeters+/−20%.

12. The substrate package of claim 8, wherein:
a first edge of the one or more perimeter edges has a length in a range of 10 millimeters (mm)+/−20% to 250 mm+/−20%; and
a second edge of the one or more perimeter edges is perpendicular to the first edge and has a length in a range of 10 mm+/−20% to 250 mm+/−20%.

13. The substrate package of claim 8, further comprising:
an integrated circuit (IC) die attached on the upper surface of the first dielectric layer; and
an encapsulant overlaid across the IC die.

14. The substrate package of claim 13, further comprising solder bumps attached to the lower surface of the second dielectric layer.

15. The substrate package of claim 8, further comprising:
a first layer of the mold material between the first dielectric layer and the layer of glass;
a second layer of the mold material between the layer of glass and the second dielectric layer; and
wherein the first layer of the mold material, the second layer of the mold material, and the mold material in the one or more cavities are contiguous.

16. The substrate package of claim 15, further comprising:
an integrated circuit (IC) die attached on the upper surface of the first dielectric layer; and
solder bumps attached to the lower surface of the second layer.

17. A system, comprising:
the substrate package of claim 14; and
a printed circuit board attached to the solder bumps.

18. A method, comprising:
etching a first top side of a first layer of glass to create a first high taper edge from the first top side to a first bottom side;
etching a second top side of a second layer of glass to create a second high taper edge from the second top side to a second bottom side;
fusing the first top side to the second top side to thereby create a glass core with a riveted edge;
patterning the glass core with the riveted edge with through-glass vias (TGVs) and redistribution layers to thereby create a unit;
reconstituting the unit with a plurality of similar units thereby creating a panel, wherein reconstituting includes at least partially filling the riveted edge with a mold material.

19. The method of claim 18, further comprising:
adding dielectric layers and additional redistribution layers to the units.

20. The method of claim 19, further comprising singulating the panel into discrete systems.
